(19) United States
(12) Patent Application Publication
(10) Pub. No.: US 2013/0058054 A1
(43) Pub. Date: Mar. 7, 2013

(54) FIXING APPARATUS FOR EXPANSION CARD

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY(ShenZhen) CO., LTD., Shenzhen City (CN)

(21) Appl. No.: 13/277,232

(22) Filed: Oct. 20, 2011

(30) Foreign Application Priority Data
Sep. 7, 2011 (CN) 201110263520.8

(51) Int. Cl. H05K 7/00

(52) U.S. Cl. 361/748

(57) ABSTRACT

An apparatus for fixing an expansion card includes a circuit board, a fixing device, and a latching device. The expansion card includes a protrusion formed on a first end of the expansion card, and a positioning hole defined adjacent to a second end of the expansion card away from the first end. The fixing device is mounted to the circuit board for supporting the first end of the expansion card, and defines a through hole for allowing the protrusion of the expansion card to extend through the through hole. The latching device is mounted to the circuit board for supporting the second end of the expansion card, and includes a post for engaging in the positioning hole of the expansion card, and a resilient hook for engaging with a top of the expansion card.

### BACKGROUND

1. Technical Field

The present disclosure relates to an apparatus for fixing an expansion card.

2. Description of Related Art

In an electronic device, some expansion cards are mounted to a circuit board with screws. However, those screws are usually small and difficult to handle, and the installation of the expansion cards in the electronic device is tedious.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an exploded, isometric view of an exemplary embodiment of a fixing apparatus together with an expansion card.

FIG. 2 is an inverted view of FIG. 1.

FIG. 3 is an assembled, isometric view of FIG. 1.

FIG. 4 is a cross-sectional view taken along the line IV-IV of FIG. 3.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

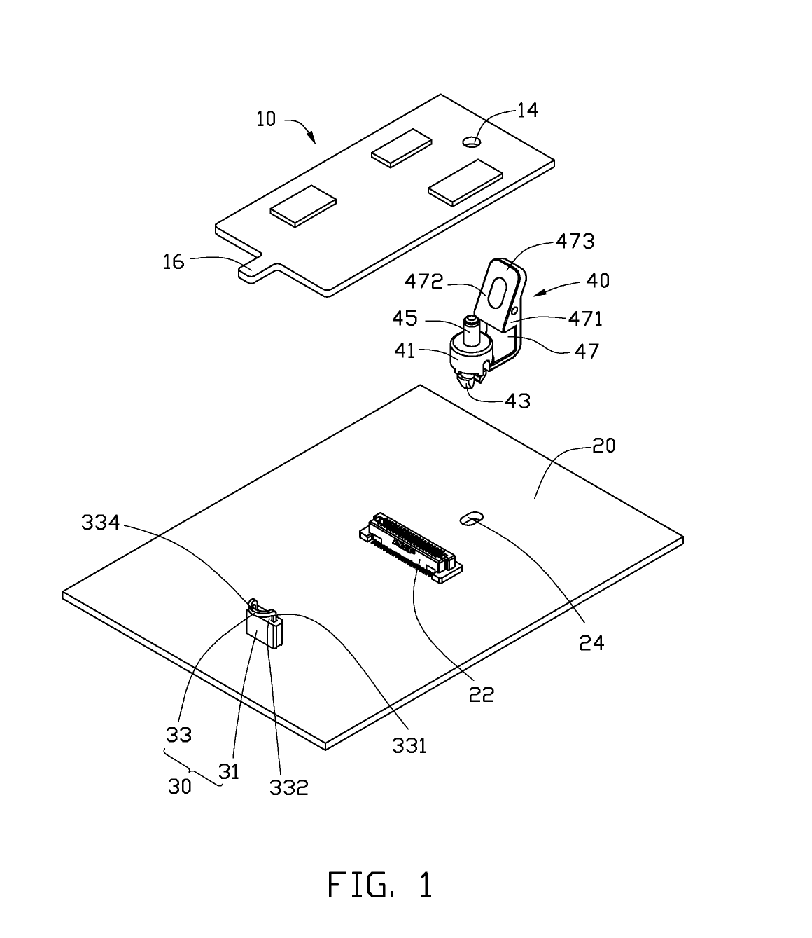

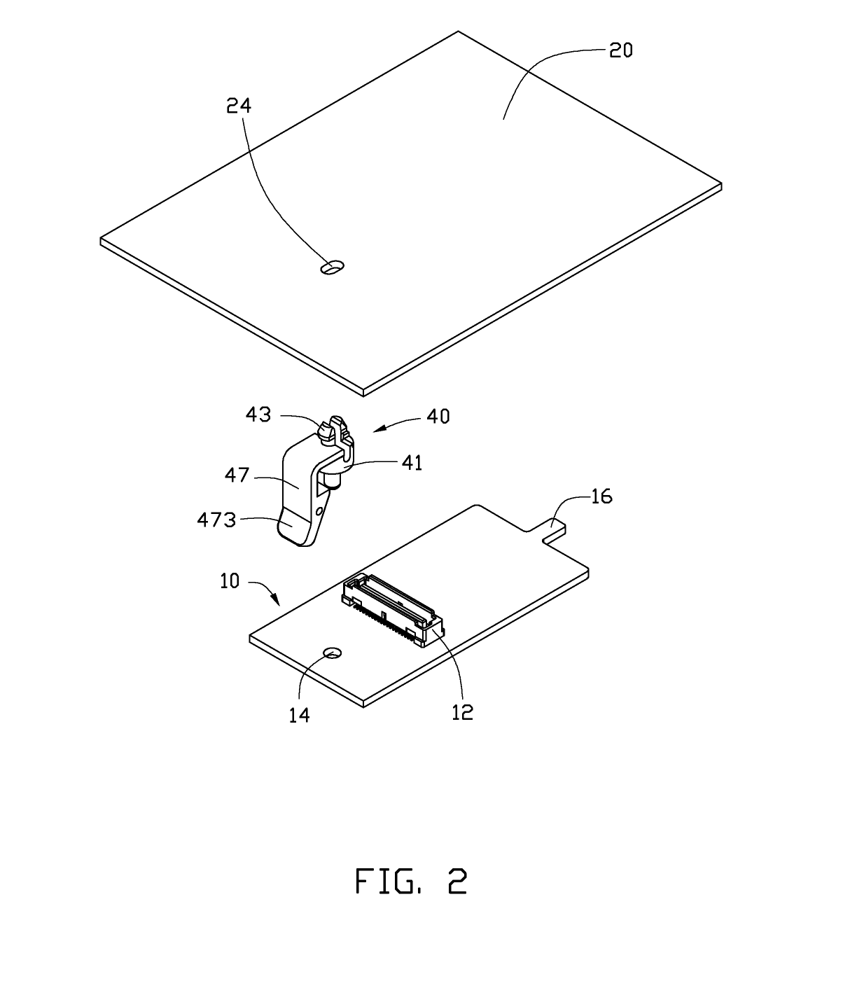

Referring to FIGS. 1 and 2, an exemplary embodiment of a fixing apparatus is provided to fix an expansion card 10. The fixing apparatus includes a circuit board 20, a fixing device 30, and a latching device 40.

A first connector 12 is installed on the bottom of the expansion card 10. A positioning hole 14 is defined in the expansion card 10 adjacent to a first end of the expansion card 10. A protrusion 16 extends from a second end of the expansion card 10 away from the first end.

A second connector 22 is installed on the top of the circuit board 20, for being electrically connected to the first connector 12. A fixing hole 24 is defined in the circuit board 20 at a side of the second connector 20.

The fixing device 30 includes a block 31, and a retaining portion 33 formed on the top of the block 31. The retaining portion 33 is a bent metal rod, and includes two opposite arms 331 connected to the top of the block 31, and an arc-shaped connecting portion 334 horizontally connected between the tops of the arms 331. A through hole 332 is bounded by the retaining portion 33 and the top of the block 31.

The latching device 40 includes a base 41. Two resilient feet 43 extend down from the bottom of the base 41. A post 45 extends up from a middle of the top of the base 41. A resilient hook 47 extends out and up from a lateral side of the base 41. The hook 47 includes a hooking portion 471 extending toward the post 45. The hooking portion 471 includes a slanted surface 472 facing the post 45. An operation portion 473 is formed on the top of the hooking portion 471.

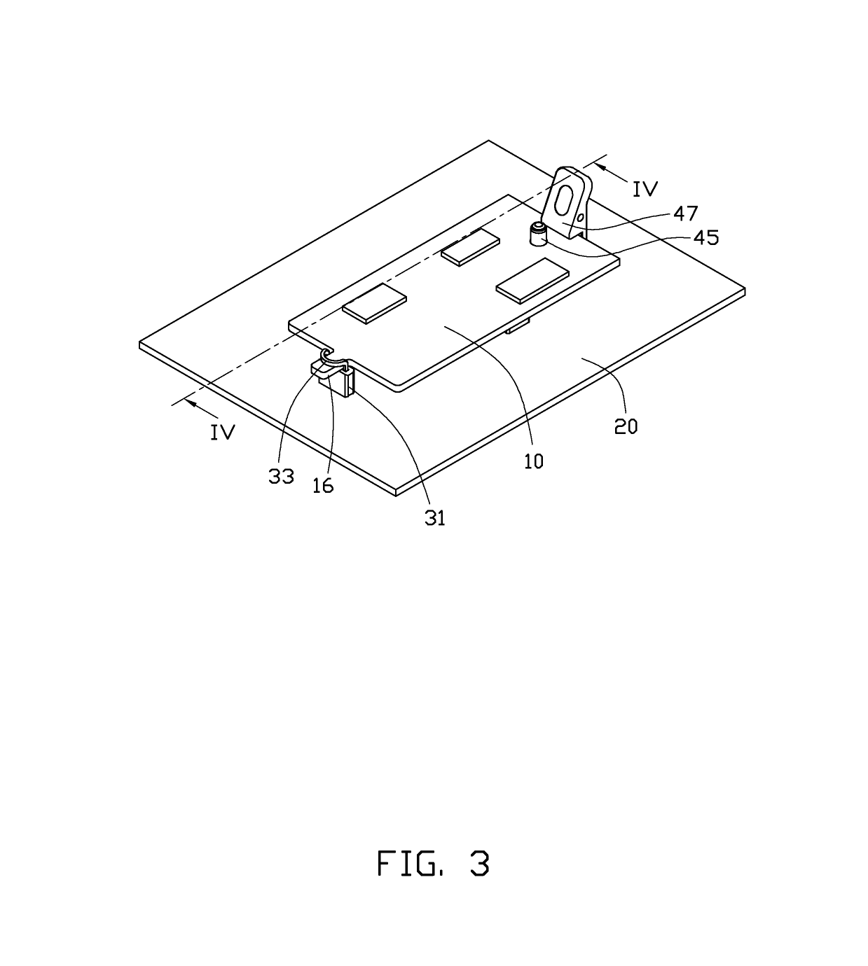

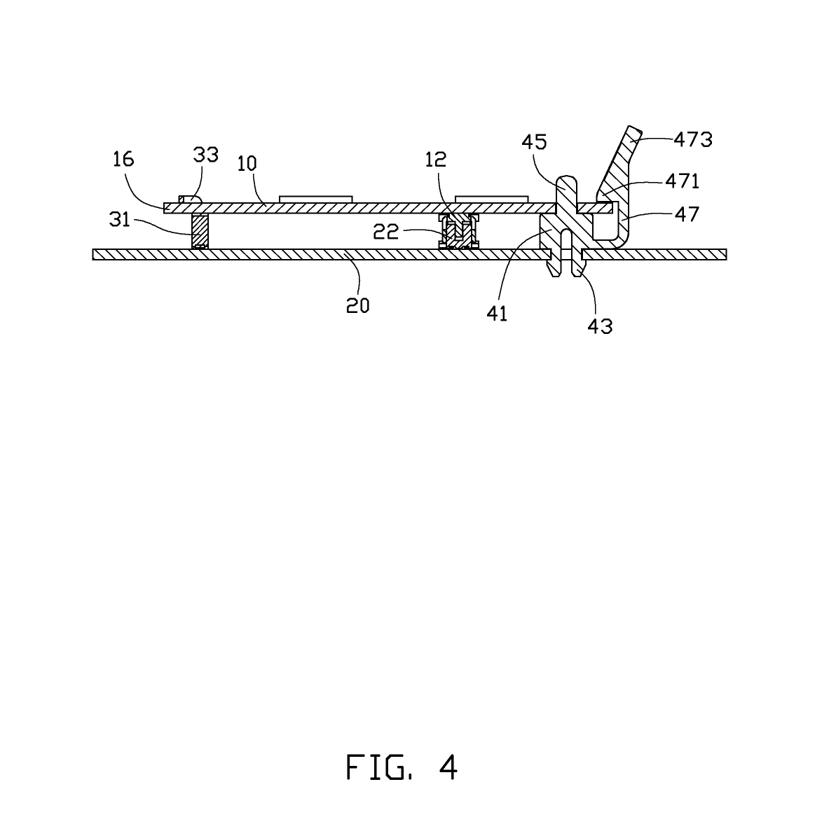

Referring to FIGS. 3 and 4, in assembly, the block 31 is mounted to the circuit board 20 at an opposite side of the second connector 20 away from the fixing hole 24 by welding or latching portions. The feet 43 are deformed towards each other to extend through the fixing hole 24. The feet 43 are then restored to engage with the bottom of the circuit board 20, to allow the latching device 40 to be fixed to the circuit board 20. The hooking portion 471 is arranged to face the second connector 22. The protrusion 16 is extended through the through hole 332 and supported on the block 31. The first end of the expansion card 10 is rotated down, to allow the first end of the expansion card 10 to push the slanted surface 472. The hook 47 is deformed away from the expansion card 10. The post 45 is extended through the positioning hole 14. The first connector 12 is connected to the second connector 22. When the first end of the expansion card 10 is supported on the base 41, the first connector 12 is completely connected to the second connector 22. The hook 47 is restored to allow the hooking portion 471 to engage with the top of the expansion card 10. Thereby, the expansion card 10 is fixed to the circuit board 20.

To detach the expansion card 10 from the circuit board 20, the operation portion 473 is pulled away from the expansion card 10, to allow the hooking portion 471 to disengage from the expansion card 10. The first end of the expansion card 10 is rotated up, to allow the first connector 12 to disengage from the second connector 22, and to allow the post 45 to exit from the positioning hole 14. The expansion card 10 is moved away from the fixing device 30, to allow the protrusion 16 to exit from the through hole 332. Thereby, the expansion card 10 is detached from the circuit board 20.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A fixing apparatus for an expansion card, the expansion card comprising a protrusion formed on a first end of the expansion card, and a positioning hole defined adjacent to a second end of the expansion card away from the first end, the fixing apparatus comprising:
a circuit board;
a fixing device mounted to the circuit board for supporting the first end of the expansion card, the fixing device defining a through hole, for allowing the protrusion of the expansion card to extend through the through hole; and
a latching device mounted to the circuit board, for supporting the second end of the expansion card, the latching device comprising a post for engaging in the positioning hole of the expansion card, and a resilient hook for engaging with a top of the expansion card.

2. The fixing apparatus of claim 1, wherein the fixing device comprises a block mounted to the circuit board, and a retaining portion formed on a top of the block, the through hole is defined in the retaining portion.

3. The fixing apparatus of claim 2, wherein the retaining portion is a bent metal rod, and includes two opposite arms connected to the top of the block, and an arc-shaped connecting portion horizontally connected between tops of the arms, the through hole is bounded by the retaining portion and the top of the block.

4. The fixing apparatus of claim 1, wherein the latching device comprises a base mounted to the circuit board, the post extends up from a middle of a top of the base.

5. The fixing apparatus of claim 4, wherein the hook extends out and up from a lateral side of the base, the hook comprises a hooking portion extending toward the post, for engaging with the top of the expansion card.

6. The fixing apparatus of claim 5, wherein the hooking portion comprises a slanted surface facing the post.

7. The fixing apparatus of claim 5, wherein an operation portion is formed on a top of the hooking portion.

8. The fixing apparatus of claim 4, wherein a fixing hole is defined in the circuit board, two resilient feet extend down from a bottom of the base, to extend through the fixing hole and engage with a bottom of the circuit board.

9. The fixing apparatus of claim 1, wherein the fixing device is mounted to the circuit board by welding.

10. The fixing apparatus of claim 1, wherein a first connector is mounted to the circuit board between the fixing device and the latching device, for being electrically connected to a second connector of the expansion card.
